(19) United States
(12) Patent Application Publication
(10) Pub. No.: US 2025/0337433 A1
(43) Pub. Date: Oct. 30, 2025

(54) DEVICE AND METHOD FOR ANALOG-TO-DIGITAL CONVERSION

(71) Applicant: SAMSUNG ELECTRONICS CO., LTD., SUWON-SI (KR)

(72) Inventors: TAEWOONG KIM, SUWON-SI (KR); JAEHOON LEE, SUWON-SI (KR); YONG LIM, SUWON-SI (KR)

(21) Appl. No.: 19/045,834

(22) Filed: Feb. 5, 2025

(30) Foreign Application Priority Data
Apr. 29, 2024 (KR) 10-2024-0057038

(51) Int. Cl. H03M 1/46

(52) U.S. Cl. CPC H03M 1/46

(57) ABSTRACT

An analog-to-digital converter (ADC) includes a first digital-to-analog converter (DAC) configured to change a signal level of a first node based on a first and second input analog signals, a second DAC configured to change a signal level of a second node based on one of the first input analog signal and the second input analog signal, a comparator configured to compare the signal level of the first node and the signal level of the second node, and a controller configured to generate a first digital value for the first DAC and a second digital value for the second DAC based on an output of the comparator during a first conversion phase corresponding to a first sampling phase, input the first digital value into the second DAC before a second sampling phase, and input the second digital value into the first DAC before the second sampling phase.

### CROSS-REFERENCE TO RELATED APPLICATION

This patent application claims priority under 35 U.S.C. § 119 to Korean Patent Application No. 10-2024-0057038 filed on Apr. 29, 2024, in the Korean Intellectual Property Office, the entire disclosure of which is incorporated by reference in its entirety herein.

### 1. Technical Field

This disclosure is directed to a device and method for analog-to-digital conversion.

### 2. Discussion of Related Art

An analog-to-digital converter (ADC) is a device for converting an analog signal into a digital signal. A successive-approximation register (SAR) ADC is a type of ADC. The SAR ADC may estimate an output digital value corresponding to an input analog signal by using a binary search algorithm. It operates by successively narrowing down the range in which the analog input resides, one bit at a time, until the digital output accurately represents the analog input.

A reference voltage used by the SAR ADC may not settle properly before its logic needs to make a comparison, which can lead to setting errors that reduce the accuracy of the output digital value. Further, the settling time of the SAR ADC may be insufficient, which can limit its effective resolution.

Thus, there is a need for a SAR ADC that reduces settling times and eliminates setting errors.

### SUMMARY

According to an embodiment, there is provided an analog-to-digital converter (ADC) including a first digital-to-analog converter (DAC) configured to change a signal level of a first node based on one of a first input analog signal and a second input analog signal; a second DAC configured to change a signal level of a second node based on one of the first input analog signal and the second input analog signal; a comparator configured to compare the signal level of the first node and the signal level of the second node; and a controller configured to generate a first digital value for the first DAC and a second digital value for the second DAC based on an output of the comparator during a first conversion phase corresponding to a first sampling phase, input the first digital value into the second DAC before a second sampling phase, and input the second digital value into the first DAC before the second sampling phase.

According to an embodiment, there is provided an ADC including a first DAC configured to change a signal level of a first node based on one of a first input analog signal and a second input analog signal; a second DAC configured to change a signal level of a second node based on one of the first input analog signal and the second input analog signal; a comparator configured to compare the signal level of the first node and the signal level of the second node; a controller configured to generate an output digital value corresponding to a difference between respective sample values obtained from the first input analog signal and the second input analog signal during a sampling phase corresponding to a conversion phase, based on values output from the comparator during the conversion phase; and a code swap circuit configured to input an input digital value of the first DAC generated during a first conversion phase corresponding to a first sampling phase into the second DAC before a second sampling phase, and input an input digital value of the second DAC generated during the first conversion phase into the first DAC before the second sampling phase.

According to an embodiment, there is provided a method including: changing a signal level of a first node and a signal level of a second node separately based on a corresponding input analog signal of a first input analog signal and a second input analog signal; comparing, using a comparator, the signal level of the first node and the signal level of the second node; inputting, using a controller, an input digital value of a first DAC generated during a first conversion phase corresponding to a first sampling phase into a second DAC before a second sampling phase; and inputting an input digital value of the second DAC generated during the first conversion phase into the first DAC before the second sampling phase, where the first DAC is coupled to the first node and the second DAC is coupled to the second node.

According to an embodiment, an analog-to-digital converter (ADC) includes: a first digital-to-analog converter (DAC) configured to adjust a first voltage at a first node based on a first input analog signal to match a first digital value provided by the controller; a second DAC configured to adjust a second voltage at a second node based on a second input analog signal to match a second digital value provided by the controller; a comparator configured to compare the signal level of the first node and the signal level of the second node; and a controller configured to generate the first and second digital values based on an output of the comparator during a first conversion phase corresponding to a first sampling phase, input the first digital value into the second DAC before a second sampling phase, and input the second digital value into the first DAC before the second sampling phase.

### BRIEF DESCRIPTION OF THE DRAWINGS

These and/or other aspects and features of the inventive concept will become apparent and more readily appreciated from the following description of embodiments, taken in conjunction with the accompanying drawings of which:

FIG. 1 is a circuit diagram illustrating a successive-approximation register analog-to-digital converter (SAR ADC) according to an embodiment;

FIG. 2 is a flowchart illustrating an operation of a SAR ADC according to an embodiment;

FIG. 3 is a timing diagram illustrating an operation of the SAR ADC of FIG. 1;

FIG. 4 is a diagram illustrating averaging performed by the SAR ADC of FIG. 1;

FIGS. 5 and 6 are circuit diagrams illustrating a SAR ADC according to an embodiment;

FIG. 7 is a timing diagram illustrating an operation of the SAR ADC of FIG. 5;

FIG. 8 is a diagram illustrating averaging performed by the SAR ADC of FIG. 5;

FIGS. 9A, 9B, and 10 are diagrams illustrating errors related to the SAR ADC of FIG. 5;

FIGS. 11 and 12 are circuit diagrams illustrating a SAR ADC according to an embodiment;

FIG. 13 is a timing diagram illustrating a code swap performed by the SAR ADC of FIGS. 11 and 12; and

FIG. 14 is a flowchart illustrating an analog-to-digital conversion method according to an embodiment.

### DETAILED DESCRIPTION

Hereinafter, embodiments will be described in detail with reference to the accompanying drawings. When describing the embodiments with reference to the accompanying drawings, like reference numerals refer to like components, and any repeated description related thereto will be omitted.

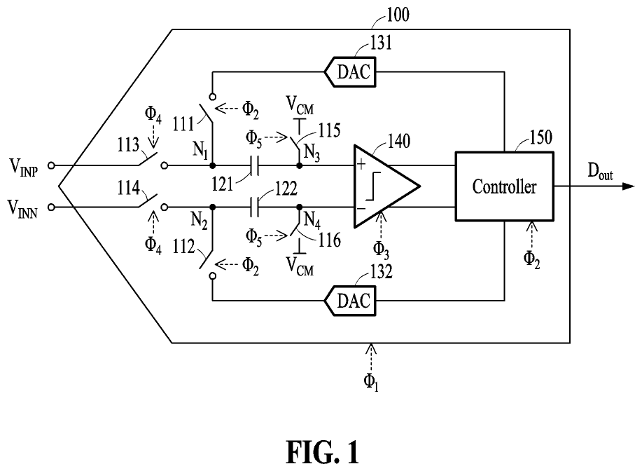

FIG. 1 is a circuit diagram illustrating a successive-approximation register analog-to-digital converter (SAR ADC) according to an embodiment.

Referring to FIG. 1, according to an embodiment, a SAR ADC 100 includes a plurality of switches 111 to 116, a plurality of capacitors 121 and 122, one or more digital-to-analog converters (DACs) 131 and 132, a comparator 140, and a controller 150 (e.g., SAR logic, a control circuit, etc.). For ease of description, the present disclosure is described using a differential input as an example, but it is apparent to one of ordinary skill in the art that the technical idea of the disclosure may also apply to a single-ended input. The differential input may measure the difference in voltage between two signal lines, whereas the single-ended input may measure the voltage of a single signal line relative to reference voltage (e.g., a common ground).

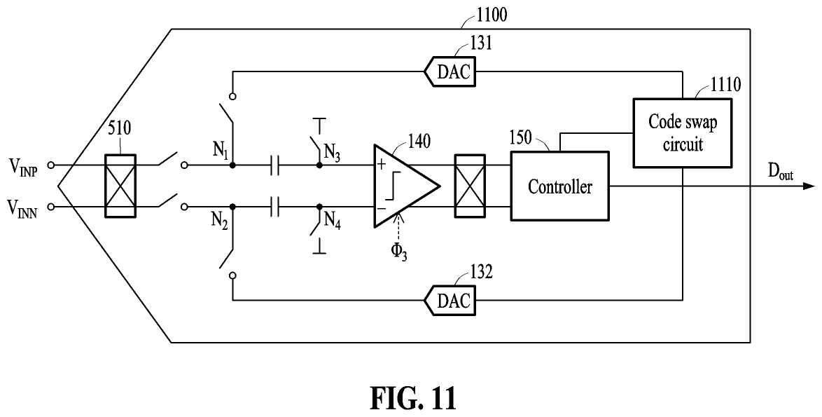

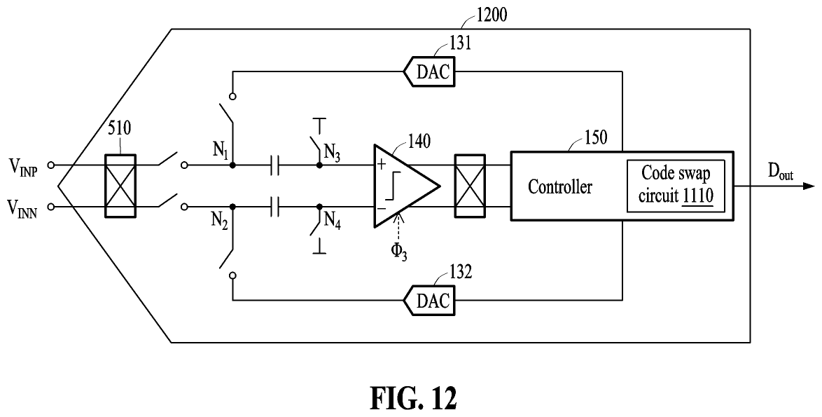

The components of a SAR ADC described herein (e.g., the SAR ADC 100 of FIG. 1, a SAR ADC 500 of FIG. 5, a SAR ADC 1100 of FIG. 11, or a SAR ADC 1200 of FIG. 12) are examples to describe the technical idea of the disclosure, but the scope of the disclosure is not limited thereto.

The SAR ADC 100 is driven by a clock signal Φ₁. The clock signal Φ₁ and other clock signals to be described below may have a consistent and repeating waveform such as a square wave.

The switches 113 and 114 may couple input analog signals V_{INP} and V_{INN} to the capacitors 121 and 122, respectively, to sample the input analog signals V_{INP} and V_{INN}. For ease of description, it is assumed that signal levels (e.g., voltages or potentials) of the input analog signals V_{INP} and V_{INN} are constant. The switches 113 and 114 may operate based on a clock signal Φ₄ for a sampling phase. For example, the switches 113 and 114 may be closed when the clock signal Φ₄ is “high” and open when a clock signal Φ₅ is “low.” Herein, a sampling phase may be a phase of capturing and/or holding an input analog signal, and a conversion phase may be a phase of determining a digital value (or digital code) corresponding to a signal level (or sample value) of a sample obtained during a sampling phase, using a successive approximation algorithm.

The switch 111 may couple a signal level (e.g., voltage or potential) of an analog signal output from the DAC 131 to a node N₁. The switch 112 may couple a signal level of an analog signal output from the DAC 132 to a node N₂. The switches 111 and 112 may operate based on a clock signal Φ₂ for a conversion phase. For example, the switches 111 and 112 may be closed when the clock signal Φ₂ is “high” and open when the clock signal Φ₅ is “low.”

The switches 115 and 116 may apply a common mode voltage V_{CM} to nodes N₃ and N₄. The switches 115 and 116 may operate based on the clock signal Φ₅ for the sampling phase. For example, the switches 115 and 116 may be closed when the clock signal Φ₅ is “high” and open when the clock signal Φ₅ is “low”.

In an embodiment, the switches 111-116 are implemented by transistors whose gates receive a corresponding one of the above-described clock signals.

The capacitors 121 and 122 may sample and/or hold the input analog signals V_{INP} and V_{INN}. For example, the capacitor 121 may be charged based on the difference between the signal level of the first input analog signal V_{INP} and the common mode voltage V_{CM}, during the sampling phase. Likewise, the capacitor 122 may be charged based on the difference between the signal level of the second input analog signal V_{INN} and the common mode voltage V_{CM}, during the sampling phase. Since the capacitors 121 and 122 are in a floating state during the conversion phase, the potential difference between two plates (e.g., conductive plates) of each of the capacitors 121 and 122 during the conversion phase may be maintained constant as a potential difference formed during the sampling phase. For example, when the signal level of the first input analog signal V_{INP} is 7.5 voltages (V) and the common mode voltage V_{CM} is 2.5 V, the potential difference between the two plates of the capacitor 121 may be maintained at 5V during the conversion phase.

The DACs 131 and 132 may convert a digital value generated by the controller 140 into an analog signal (e.g., analog voltage).

The comparator 140 may compare the signal level of the node N₃ with the signal level of the node N₄ to generate a comparison result. The comparator 140 may output a digital value (e.g., “0” or “1”) based on the comparison result. For example, the comparator 140 may generate the digital value “1” when the signal level of the node N₃ is higher than the signal level of the node N₄, and generate the digital value “0” when the signal level of the node N₃ is lower than the signal level of the node N₄. The comparator 140 may operate based on a clock signal Φ₃ for driving the comparator 140. For example, the comparator 140 may initiate a comparison operation at a rising edge of the clock signal Φ₃.

Based on the output (e.g., the digital value of “0” or “1”) of the comparator 140, the controller 150 may sequentially determine the output digital value D_{OUT} of the ADC 100 from the most significant bit (MSB) to the least significant bit (LSB). The controller 150 may sequentially (or gradually) determine the respective input digital values of the DACs 131 and 132 based on the output of the comparator 140, for a successive approximation. For example, the respective input digital values may be determined incrementally through multiple steps within a same conversion phase. Since the successive approximation is an algorithm commonly used in SAR DACs, a detailed description thereof is omitted. After the value of the LSB is determined, the controller 150 may output the output digital value D_{OUT} of the ADC 100.

The accuracy of the SAR ADC 100 may be affected by noise and/or offset voltage of the components of the SAR ADC 100. For example, the offset voltage of the comparator 120 may lower the accuracy of the SAR ADC 100. The offset voltage of the comparator 120 may be the minimum input voltage difference required to change the output state (e.g., “0” or “1”) of the comparator 120. An ideal comparator would switch the output when two input voltages are equal, but in reality, a comparator would switch the output when the difference between the two input voltages is greater than an offset voltage (e.g.: 1 millivolt (mV)). To increase the accuracy of the SAR DAC, a chopper (e.g., a chop switch) may be used. SAR DACs including choppers will be described in detail with reference to FIGS. 5 to 13.

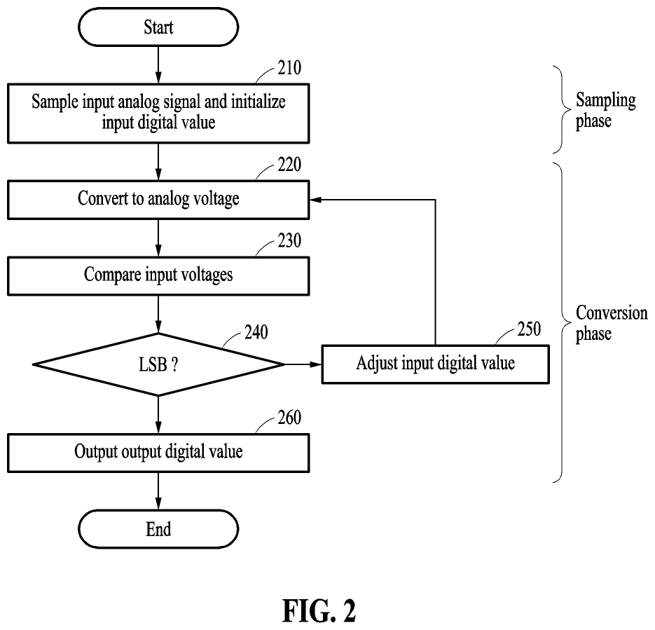

FIG. 2 is a flowchart illustrating an operation of a SAR ADC according to an embodiment.

Referring to FIG. 2, according to an embodiment, operation 210 is performed during a sampling phase, and operations 220 to 260 are performed during a conversion phase. Operations 210 to 260 may be operations of a SAR ADC (e.g., the SAR ADC 100 of FIG. 1, the SAR ADC 500 of FIG. 5, the SAR ADC 1100 of FIG. 11, or the SAR ADC 1200 of FIG. 12) that are schematically shown to describe the disclosure.

In operation 210, the SAR ADC 100, 500, 1100, or 1200 samples and/or holds an input analog signal (e.g., a single-ended signal (not shown) or a differential input signal such as the input analog signal V_{INP} or V_{INN} of FIG. 2). The SAR ADC 100, 500, 1100, or 1200 may initialize an input digital value (or input digital code) of a DAC (e.g., the DAC 131 or 132 of FIGS. 1, 5, 11, and 12). For example, when the SAR ADC 100, 500, 1100, or 1200 is a 5-bit SAR ADC for processing a differential input, the initial input digital value may be “00000”.

In operation 220, the SAR ADC 100, 500, 1100, or 1200 generates an analog voltage corresponding to the input digital value of the DAC 131 or 132.

In operation 230, the SAR ADC 100, 500, 1100, or 1200 compares two input voltages of a comparator (e.g., the comparator 140 of FIGS. 1, 5, 11, and 12) with each other to generate a comparison result. As described with reference to FIG. 1, the two input voltages of the comparator (e.g., the signal level of the node N₃ and the signal level of the node N₄ of FIG. 1) may be changed sequentially (or gradually) based on the output (e.g., the analog voltage) of the DAC 131 or 132, generated in operation 230.

In operation 240, the SAR ADC 100, 500, 1100, or 1200 determines the value of the current bit based on the comparison result. The SAR ADC 100, 500, 1100, or 1200 may determine whether the current bit is the LSB of the output digital value.

In operation 250, the SAR ADC 100, 500, 1100, or 1200 may adjust (or change) the input digital value of the DAC to determine the value of the next bit (e.g., lower bit) when it is determined in operation 240 that the current bit is not the LSB. The SAR ADC 100, 500, 1100, or 1200 may repeatedly perform operations 230 to 260 until the LSB of the output digital value is determined based on a successive approximation algorithm.

In operation 260, the SAR ADC 100, 500, 1100, or 1200 outputs the output digital value when the LSB of the output digital value is determined. The output digital value may be an approximate digital value corresponding to the signal level (e.g., voltage or sample value) of a sample obtained from the input analog signal.

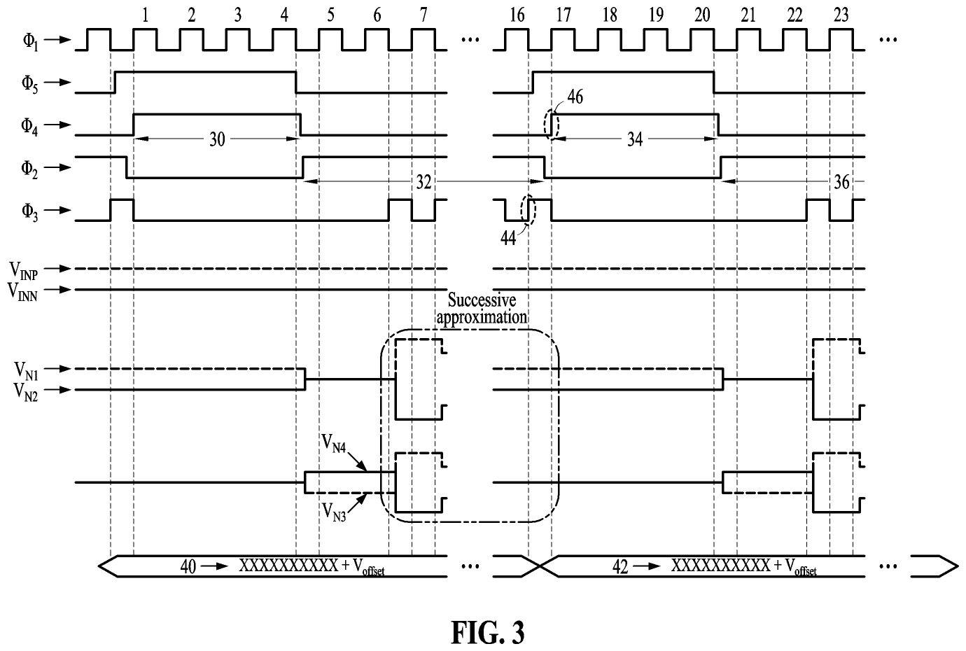

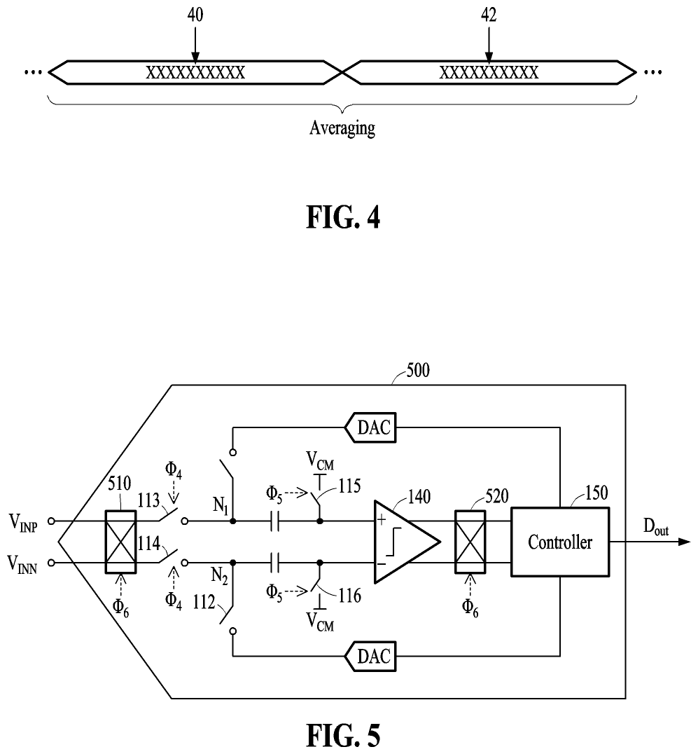

FIG. 3 is a timing diagram illustrating an operation of the SAR ADC of FIG. 1, and FIG. 4 is a diagram illustrating averaging performed by the SAR ADC of FIG. 1. FIG. 3 is a typical timing diagram of a successive approximation algorithm, and a detailed description thereof is omitted.

Referring to FIGS. 3 and 4, according to an embodiment, a SAR ADC (e.g., the SAR ADC 100 of FIG. 1) may generate a plurality of digital values for an input analog signal, for averaging. In a SAR ADC, “averaging” may refer to the process of obtaining multiple samples of an input analog signal and calculating the average of respective output digital values corresponding to the multiple samples, to increase the accuracy of the SAR ADC. Output digital values for averaging may be obtained during respective corresponding phases. For example, a first output digital value may be obtained during a first phase, and a second output digital value may be obtained during a second phase. As described above, each of the phases may include a sampling phase and a conversion phase.

The SAR ADC 100 may generate a first output digital value 40 corresponding to a first sample (e.g., the difference between the signal level of the first input analog signal V_{INP} and the signal level of the second input analog signal V_{INN}) via a first sampling phase 30 and a first conversion phase 32, and generate a second output digital value 42 corresponding to a second sample via a second sampling phase 34 and a second conversion phase 36. The first sample may be a sample obtained during the first sampling phase 30, and the second sample may be a sample obtained during the second sampling phase 34. FIGS. 3 and 4 show two output digital values 40 and 42 and timing diagrams therefor, but are merely examples for describing the disclosure, and the SAR ADC (e.g., the SAR ADC 100 of FIG. 1, the SAR ADC 500 of FIG. 5, the SAR ADC 1100 of FIG. 11, or the SAR ADC 1200 of FIG. 12) may generate respective output digital values corresponding to a plurality of samples.

The last rising edge 44 of the clock signal Φ₃ for driving a comparator (e.g., the comparator 140 of FIG. 1) within the first conversion phase 32 may be for determining the LSB of the first output digital value 40. The potential of a node (e.g., the node N₁ or the node N₂ of FIG. 1) connected to a DAC (e.g., the DAC 131 or 132 of FIG. 1) may converge to an approximation of the signal level of the input analog signal (e.g., the first input analog signal V_{INP} or the second input analog signal V_{INN}), between the last rising edge 44 of the clock signal Φ₃ and a rising edge 46 of the clock signal Φ₄ for the second conversion phase 34.

The accuracy of the SAR ADC 100 may be increased through averaging, but the offset voltage issue of the comparator 140 may be difficult to resolve by averaging. To address the offset voltage issue, a SAR ADC (e.g., the SAR ADC 500 of FIG. 5, the SAR ADC 1100 of FIG. 11, or the SAR ADC 1200 of FIG. 12) including a chopper (e.g., a chop switch) is used in an embodiment of the inventive concept.

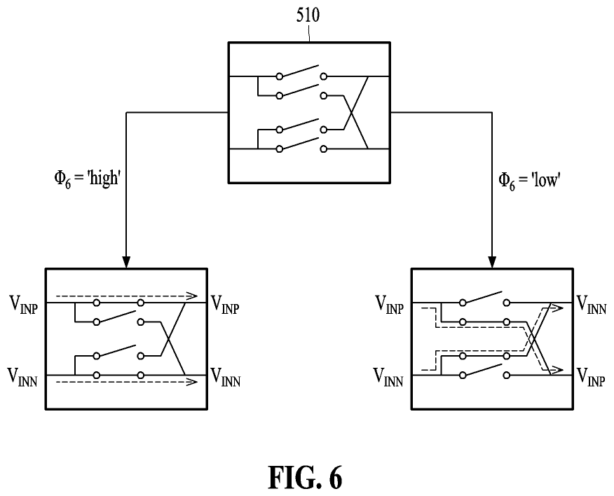

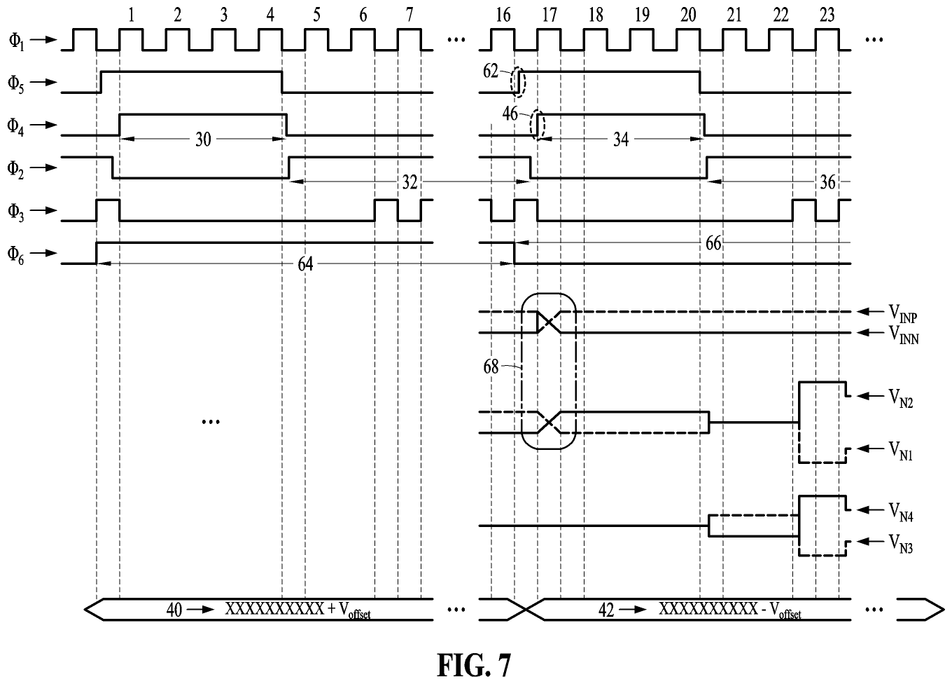

FIGS. 5 and 6 are circuit diagrams illustrating a SAR ADC according to an embodiment, and FIG. 7 is a timing diagram illustrating an operation of the SAR ADC of FIG. 5. The configuration and operation of the SAR ADC 500 may be similar to the configuration and operation of the SAR ADC 100 described with reference to FIG. 1. Accordingly, a repeated description is omitted.

Referring to FIGS. 5 to 7, according to an embodiment, the SAR ADC 500 may include the components of the SAR ADC 100 described with reference to FIG. 1, and one or more choppers (e.g., a chopper 510 and a chopper 520). A repeated description is omitted.

The number of choppers included in the SAR ADC 500 may vary based on the configuration of the SAR ADC 500. For example, the chopper 520 at an output stage may be omitted when the controller 150 includes a component (e.g., circuit) capable of functioning as the chopper 520. The choppers 510 and 520 may operate based on a clock signal Φ₆ for driving the choppers 510 and 520.

The chopper 510 may selectively couple (or electrically connect) one of the input analog signals V_{INP} and V_{INN} to the node N₁ and couple the other one to the node N₂, based on the clock signal Φ₆. For example, when the clock signal Φ₆ is “high,” the chopper 510 may couple the first input analog signal V_{INP} to the node N₁ and couple the second input analog signal V_{INN} to the node N₂.

The clock signal Φ₆ may transition gradually in response to respective phases for generating a plurality of output digital values to be used for averaging. For example, when the clock signal Φ₆ is “high” during a time period 64 corresponding to a first phase for obtaining the first output digital value 40, the clock signal Φ₆ may be “low” during a time period 66 corresponding to a second phase for obtaining the second output digital value 42.

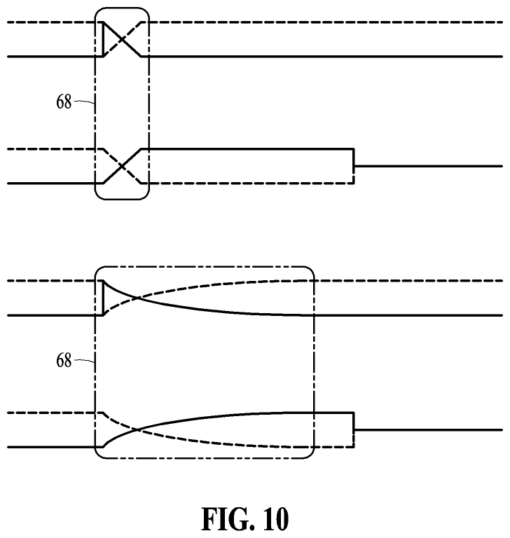

The point in time at which the clock signal Φ₆ changes may be determined based on a sampling phase. For example, the clock signal Φ₆ may change before a rising edge 62 of the clock signal Φ₅ for the sampling phase. As the state of the chopper 510 changes based on the clock signal Φ₆, a settling period 68 (or settling time) of the signal level may occur. The settling period may be a time period from a rising edge of the clock signal Φ₄ to when the signal level of each of the nodes N₁ and N₂ reaches the signal level of a corresponding input analog signal (e.g., the input analog signal V_{INP} or the input analog signal V_{INN}). If the input analog signals V_{INP} and V_{INN} of the SAR ADC 500 fail to supply sufficient power to the ADC 500, the settling period 68 may increase. As the settling period 68 increases, the probability of errors (e.g., settling errors) occurring in the SAR ADC 500 may increase. These errors may lower the accuracy of the SAR ADC 500. The errors related to the settling period 68 will be described in detail with reference to FIGS. 9 and 10.

The chopper 520 at the output stage may be configured to change the output of the comparator 140 based on the clock signal Φ₆ to generate a new output and then input the new output into the controller 150. For example, when the clock signal Φ₆ is “low,” the chopper 520 may change the output of the comparator 140 from “low” to “high” or from “high” to “low” and input the new output into the controller 150.

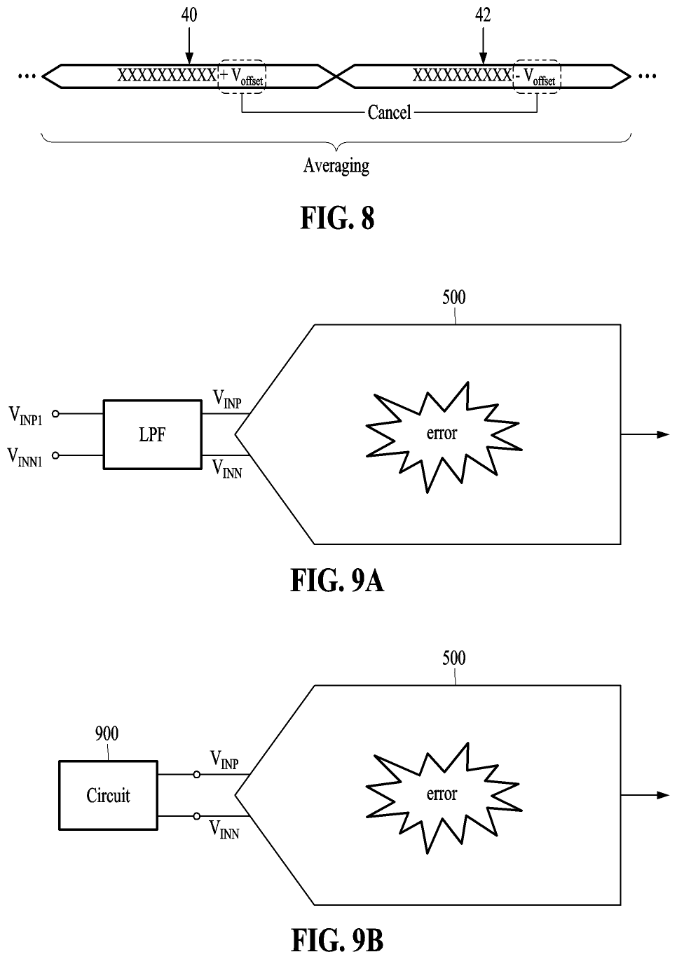

FIG. 8 is a diagram illustrating averaging performed by the SAR ADC of FIG. 5 according to an embodiment.

Referring to FIG. 8, a SAR ADC (e.g., the SAR ADC 500 of FIG. 5) may gradually reverse the polarity of an offset voltage using choppers (e.g., the choppers 510 and 520 of FIG. 5). For example, the offset voltage polarity of the first output digital value 40 may be “+”, and the offset voltage polarity of the second output digital value 42 may be “−”. The influence of the offset voltage may be minimized or eliminated by averaging the first output digital value 40 with the second output digital value 42.

The averaging may be performed by software or hardware. For example, the averaging may be performed by hardware by a controller (e.g., the controller 150 of FIG. 1, FIG. 5, FIG. 11, or FIG. 12). As another example, a processor (e.g., a microprocessor such as a digital signal processor (DSP)) (not shown) located outside the SAR ADC may execute software that performs the averaging.

FIGS. 9A, 9B, and 10 are diagrams illustrating errors related to the SAR ADC of FIG. 5.

Referring to FIGS. 9A, 9B, and 10, in the SAR ADC 500, as the state of a chopper at an input stage (e.g., the chopper 510 of FIG. 5) changes, a settling period 68 of a signal level may occur.

If the input analog signals V_{INP} and V_{INN} of the SAR ADC 500 fail to supply sufficient power to the ADC 500, the settling period 68 may increase. For example, if a low-pass filter (LPF) is applied to the input stage of the ADC 500, sufficient power may not be provided to the SAR ADC 500, and the settling period 68 may increase. As another example, the SAR ADC 500 may receive input analog signals V_{INP} and V_{INN} from another circuit 900, and if the circuit 900 fails to provide sufficient power to the SAR ADC 500, the settling period 68 may increase.

As the settling period 68 increases, the probability of errors (e.g., settling errors) occurring in the SAR ADC 500 may increase, and the errors may lower the accuracy of the SAR ADC 500. To increase the accuracy of the SAR ADC 500, it may be necessary to eliminate or reduce the settling period 68 due to the chopper 510.

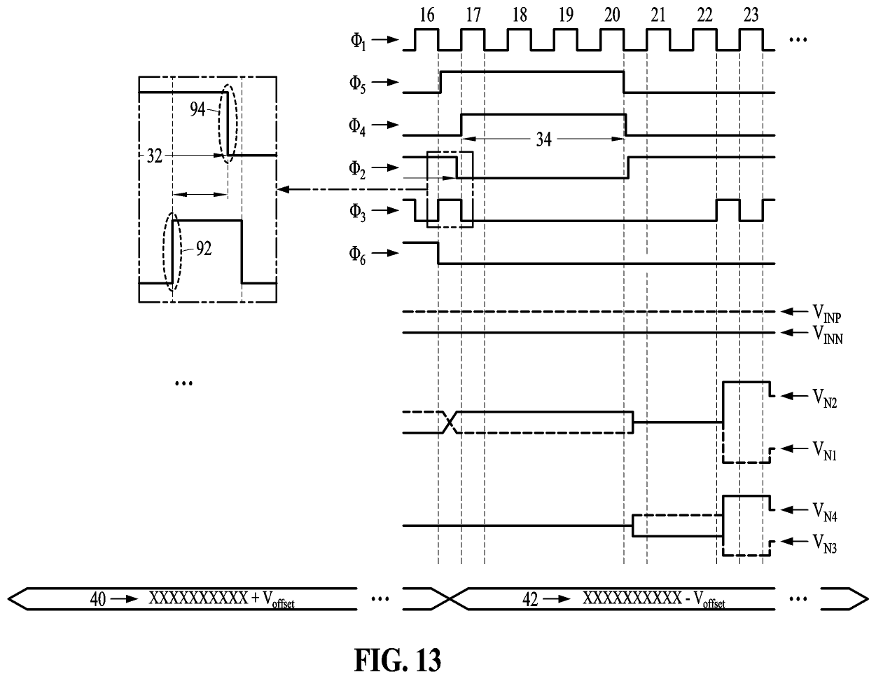

FIGS. 11 and 12 are circuit diagrams illustrating a SAR ADC according to an embodiment, and FIG. 13 is a timing diagram illustrating a code swap performed by the SAR ADC of FIGS. 11 and 12 according to an embodiment.

Referring to FIGS. 11 to 13, according to an embodiment, the SAR ADC 1100 or 1200 include a code swap circuit 1110 (e.g., a logic circuit) together with the components of the SAR ADC 100 described with reference to FIG. 1 and/or the components of the SAR ADC 500 described with reference to FIG. 5. A repeated description is omitted.

The code swap circuit 1110 may perform a code swap operation to address settling period issues caused by the chopper 510. The code swap circuit 1100 may be implemented outside of the controller 150 as in the SAR ADC 1100, or may be implemented inside the controller 150 as in the SAR ADC 1200.

The code swap circuit 1110 may swap respective input digital values of the DACs 131 and 132 generated to determine the LSB of an output digital value (e.g., the first output digital value 40) corresponding to the current phase (e.g., the first sampling phase 30). For example, to determine the LSB of the first output digital value 40, the SAR ADC 1100 or 1200 may input an input digital value corresponding to the signal level (e.g., sample value) of the first input analog signal V_{INP} into the DAC 131 and input an input digital value corresponding to the signal level of the second input analog signal V_{INN} into the DAC 132, during the first conversion phase 32. The code swap circuit 1110 may provide the input digital value of the DAC 131 used to determine the LSB of the first output digital value 40 to the DAC 132, before the second sampling phase 34. Likewise, the code swap circuit 1110 may provide the input digital value of the DAC 132 used to determine the LSB of the first output digital value 40 to the DAC 131, before the second sampling phase 34. For example, the code swap circuit 1110 may perform a code swap between the last rising edge 92 (e.g., the rising edge 44 of FIG. 3) of a clock signal Φ₃ within the first conversion phase 32 and a falling edge 94 of a clock signal Φ₂ for the first conversion phase 32. For example, if DAC 131 is set to provide a voltage corresponding to digital code 11100000 and DAC 132 is set to provide a voltage corresponding to digital code 00011000, the code swap circuit 1110 may cause DAC 131 to output the voltage for 00011000 and DAV 132 to output the voltage for 11100000.

As described above, during the second sampling phase 34, the input analog signal (e.g., the second input analog signal V_{INN}) coupled to the node N₂ during the first sampling phase (e.g., the first sampling phase 30 of FIGS. 3 and 6) may be coupled to the node N₁. Likewise, during the second sampling phase 34, the input analog signal (e.g., the first input analog signal V_{INP}) coupled to the node N₁ during the first sampling phase 30 may be coupled to the node N₂. Through the code swap, the nodes N₁ and N₂ may have, before the second sampling phase 34, the signal levels (e.g., voltages or sample values) of respective samples to be obtained during the second sampling phase 34. For example, the node N₁ may have the signal level of the second input analog signal V_{INN} before the second sampling phase 34, and the node N₂ may have the signal level of the first input analog signal V_{INP} before the second sampling phase 34. Accordingly, the SAR ADC 1100 or 1200 may resolve errors occurring due to the chopper 150 (e.g., settling errors due to the settling period).

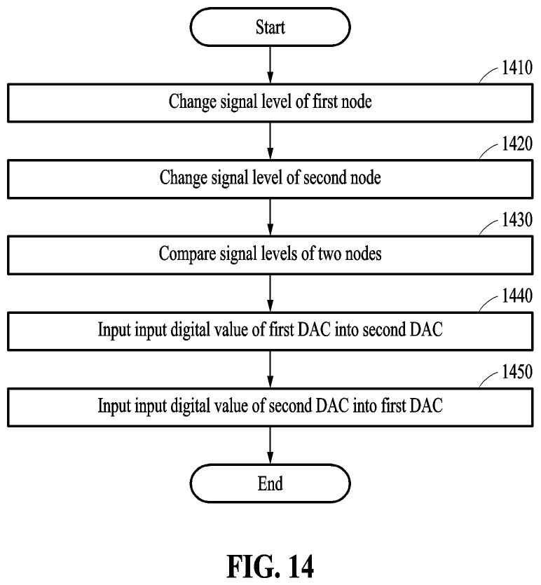

FIG. 14 is a flowchart illustrating an analog-to-digital conversion method according to an embodiment.

Referring to FIG. 14, according to an embodiment, operations 1410 to 1450 are major operations of a SAR ADC (e.g., the SAR ADC 1100 of FIG. 11 or the SAR ADC 1200 of FIG. 12), to describe the SAR ADC 1100 or 1200. The SAR ADC 1100 or 1200 may further perform one or more operations (e.g., operations 210 to 270 of FIG. 2) in addition to operations 1410 to 1450. Operations 1410 to 1440 may be performed sequentially, but embodiments are not limited thereto. For example, operations 1410 and 1420 may be performed in parallel, or operation 1440 may be performed before operation 1430. As another example, operations 1440 and 1450 may be performed in parallel, or operation 1450 may be performed before operation 1440.

In operation 1410, the SAR ADC 1100 or 1200 changes, through a DAC (e.g., the DAC 131 of FIGS. 11 and 12), the signal level of a first node (e.g., the node N₃ of FIGS. 11 and 12) based on one (e.g., the first input analog signal V_{INP}) of a first input analog signal (e.g., the first input analog signal V_{INP} of FIGS. 11 to 13) and a second input analog signal (e.g., the second input analog signal V_{INN} of FIGS. 11 to 13).

In operation 1420, the SAR ADC 1100 or 1200 changes, through a DAC (e.g., the DAC 132 of FIGS. 11 and 12), the signal level of a second node (e.g., the node N₄ of FIGS. 11 and 12) based on one (e.g., the second input analog signal V_{INN}) of the first input analog signal (e.g., the first input analog signal V_{INP} of FIGS. 11 to 13) and the second input analog signal (e.g., the second input analog signal V_{INN} of FIGS. 11 to 13).

In operation 1430, the SAR ADC 1100 or 1200 compares, through a comparator (e.g., the comparator 140 of FIGS. 11 and 12), the signal level of the first node N₃ and the signal level of the second node N₄ to generate a comparison result. The comparator 140 may generate a digital value (e.g., “0” or “1”) based on the comparison result.

In operation 1440, SAR ADC 1100 or 1200 inputs an input digital value of a first DAC (e.g., the DAC 131 of FIGS. 11 and 12) (e.g., the input digital value of the DAC 131 corresponding to the LSB) generated during a first conversion phase (e.g., the first conversion phase 32 of FIGS. 3, 7, and 13) corresponding to a first sampling phase (e.g., the first sampling phase 30 of FIGS. 3 and 7) into a second DAC (e.g., the DAC 132 of FIGS. 11 and 12) before a second sampling phase (e.g., the second sampling phase 34 of FIGS. 3, 7, and 13).

In operation 1450, the SAR ADC 1100 or 1200 inputs an input digital value of the second DAC 132 (e.g., the input digital value of the DAC 132 corresponding to the LSB) generated during the first conversion phase 32 into the first DAC 131 before the second sampling phase 34.

A SAR ADC 1100 or 1200 according to an embodiment includes a first DAC 131 configured to change the signal level of a first node N₁ based on one of the first input analog signal V_{INP} and the second input analog signal V_{INN}. For example, the first DAC 131 may adjust the voltage at the first node N₁ to match a first digital value provided by the controller 150, serving as a first reference for the comparator 140 to determine whether a differential input signal (e.g., V_{INP}−V_{INN}) is above or below this first reference during a successive approximation.

The SAR ADC 1100 or 1200 may include a second DAC 132 configured to change the signal level of a second node N₂ based on one of the first input analog signal V_{INP} and the second input analog signal V_{INN}. For example, the second DAC 132 may adjust the voltage at the second node N₂ to match a second digital value provided by the controller 150, serving as a second reference for the comparator 140 to determine whether the differential input signal is above or below this second reference during the successive approximation.

The SAR ADC 1100 or 1200 may include a comparator 140 configured to compare the signal level of the first node N₁ and the signal level of the second node N₂.

The SAR ADC 1100 or 1200 may include a controller 150 configured to input an input digital value of the first DAC 131 generated during the first conversion phase 32 corresponding to the first sampling phase 30 into the second DAC 132 before the second sampling phase 34, and input an input digital value of the second DAC 132 generated during the first conversion phase 32 into the first DAC 131 before the second sampling phase 34.

The second sampling phase 34 may be a phase for sampling the first input analog signal V_{INP} and the second input analog signal V_{INN} after obtaining an output digital value corresponding to signal levels of samples obtained during the first sampling phase 30, for averaging.

The SAR ADC 1100 or 1200 may further include a first capacitor 121 and a second capacitor 122, which are charged separately based on a corresponding input analog signal of the first input analog signal V_{INP} and the second input analog signal V_{INN} during a sampling phase.

The SAR ADC 1100 or 1200 may further include a first chopper 510 configured to couple a corresponding input analog signal of the first input analog signal V_{INP} and the second input analog signal V_{INN} separately to the first capacitor 121 and the second capacitor 122.

The SAR ADC 1100 or 1200 may further include a second chopper 520 configured to convert an output of the comparator 140.

The controller 150 may gradually or incrementally generate the input digital value of the first DAC 131 and the input digital value of the second DAC 132 during a conversion phase.

The controller 150 may input the input digital value of the first DAC 131 for determining the LSB of an output digital value of the SAR ADC 1100 or 1200 into the second DAC 132 before a second sampling phase 34, and input the input digital value of the second DAC 132 for determining the LSB into the first DAC 131 before the second sampling phase 34.

The controller 150 may input the input digital value of the first DAC 131 for determining the LSB and the input digital value of the second DAC 132 for determining a LSB into the second DAC 132 and the first DAC 131, respectively, between a falling edge 94 of a clock signal Φ₂ for the first conversion phase 32 and a last rising edge 92 of a clock signal Φ₃ for driving the comparator 140 within the first conversion phase 32.

The controller 150 may generate an output digital value corresponding to a difference between respective sample values obtained from the first input analog signal V_{INP} and the second input analog signal V_{INN} during a sampling phase corresponding to a conversion phase, based on values output from the comparator 140 during the conversion phase.

The controller 150 may perform averaging on respective output digital values of the SAR ADC generated during a plurality of conversion phases.

A SAR ADC 1100 or 1200 according to an embodiment may include a first DAC 131 configured to change the signal level of a first node N₁ based on one of the first input analog signal V_{INP} and the second input analog signal V_{INN}.

The SAR ADC 1100 or 1200 may include a second DAC 132 configured to change the signal level of a second node N₂ based on one of the first input analog signal V_{INP} and the second input analog signal V_{INN}.

The SAR ADC 1100 or 1200 may include a comparator 140 configured to compare the signal level of the first node N₁ and the signal level of the second node N₂.

The SAR ADC 1100 or 1200 may include a controller 150 configured to generate an output digital value corresponding to a difference between respective sample values obtained from the first input analog signal V_{INP} and the second input analog signal V_{INN} during a sampling phase corresponding to a conversion phase, based on values output from the comparator 140 during the conversion phase.

The SAR ADC 1100 or 1200 may include a code swap circuit configured to input an input digital value of the first DAC 131 generated during the first conversion phase 32 corresponding to the first sampling phase 30 into the second DAC 132 before the second sampling phase 34, and input an input digital value of the second DAC 132 generated during the first conversion phase 32 into the first DAC 131 before the second sampling phase 34.

A method according to an embodiment of the inventive concept may include changing a signal level of a first node N₁ and a signal level of a second node N₂ separately based on a corresponding input analog signal of a first input analog signal V_{INP} and a second input analog signal V_{INN}.

The method may include comparing, using a comparator 140, the signal level of the first node N₁ and the signal level of the second node N₂.

The method may include inputting, using a controller 150, an input digital value of a first DAC 131 generated during a first conversion phase 32 corresponding to a first sampling phase 30 into a second DAC 132 before a second sampling phase 34.

The method may include inputting an input digital value of the second DAC 132 generated during the first conversion phase 32 into the first DAC 131 before the second sampling phase 34.

The first DAC 131 may be coupled to the first node N₁. The second DAC 132 may be coupled to the second node N₂.

The second sampling phase 34 may be a phase for sampling the first input analog signal V_{INP} and the second input analog signal V_{INN} after obtaining an output digital value corresponding to signal levels of samples obtained during the first sampling phase 30, for averaging.

The method may further include coupling, using a first chopper 510, a corresponding input analog signal of the first input analog signal V_{INP} and the second input analog signal V_{INN} separately to a first capacitor 121 and a second capacitor 122.

The first capacitor 121 and the second capacitor 122 may be charged separately based on a corresponding input analog signal of the first input analog signal V_{INP} and the second input analog signal V_{INN} during a sampling phase.

The method may further include converting, using a second chopper 520, an output of the comparator 140.

The inputting of the input digital value of the first DAC 131 generated during the first conversion phase 32 into the second DAC 132 before the second sampling phase 34 may include inputting the input digital value of the first DAC 131 for determining an LSB of an output digital value into the second DAC 132 before the second sampling phase 34.

The inputting of the input digital value of the second DAC 132 generated during the first conversion phase 32 into the first DAC 131 before the second sampling phase 34 may include inputting the input digital value of the second DAC 132 for determining the LSB into the first DAC 131 before the second sampling phase 34.

The inputting of the input digital value of the first DAC 131 for determining the LSB into the second DAC 132 before the second sampling phase 34 may include inputting the input digital value of the first DAC 131 for determining the LSB into the second DAC 132, between a falling edge 94 of a clock signal Φ₂ for the first conversion phase 32 and a last rising edge 92 of a clock signal Φ₃ for driving the comparator 140 within the first conversion phase 32.

The inputting of the input digital value of the second DAC 132 for determining the LSB into the first DAC 131 before the second sampling phase 34 may include inputting the input digital value of the second DAC 132 for determining the LSB into the first DAC 131, between a falling edge 94 of a clock signal Φ₂ for the first conversion phase 32 and a last rising edge 92 of a clock signal Φ₃ for driving the comparator 140 within the first conversion phase 32. For example, the falling edge 94 may mark the start of the first conversion phase.

The method may further include generating, using the controller 150, an output digital value corresponding to a difference between respective sample values obtained from the first input analog signal V_{INP} and the second input analog signal V_{INN} during a sampling phase corresponding to a conversion phase, based on values output from the comparator 140 during the conversion phase.

According to an embodiment, a computer-readable storage medium storing one or more computer programs may include instructions that cause a processor to perform one of the above-described methods.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related components. It is to be understood that a singular form of a noun corresponding to an item may include one or more of the things, unless the relevant context clearly indicates otherwise. As used herein, “A or B”, “at least one of A and B”, “at least one of A or B”, “A, B or C”, “at least one of A, B and C”, and “at least one of A, B, or C”, each of which may include any one of the items listed together in the corresponding one of the phrases, or all possible combinations thereof. Terms such as “first” or “second” may simply be used to distinguish the component from other components, and do not limit the components in other aspects (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., by wire), wirelessly, or via a third element.

As used in connection with embodiments of the disclosure, the term “module” may include a unit implemented in hardware, software, or firmware, and may interchangeably be used with other terms, for example, “logic,” “logic block,” “part,” or “circuitry.” A module may be a single integral component, or a minimum unit or part thereof, adapted to perform one or more functions. For example, according to an embodiment, the module may be implemented in a form of an application-specific integrated circuit (ASIC).

According to an embodiment, one or more of the above-described methods may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least portion of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

1. An analog-to-digital converter (ADC) comprising:
a first digital-to-analog converter (DAC) configured to change a signal level of a first node based on one of a first input analog signal and a second input analog signal;
a second DAC configured to change a signal level of a second node based on one of the first input analog signal and the second input analog signal;
a comparator configured to compare the signal level of the first node and the signal level of the second node; and
a controller configured to generate a first digital value for the first DAC and a second digital value for the second DAC based on an output of the comparator during a first conversion phase corresponding to a first sampling phase, input the first digital value into the second DAC before a second sampling phase, and input the second digital value into the first DAC before the second sampling phase.

2. The ADC of claim 1, wherein the second sampling phase is for sampling the first input analog signal and the second input analog signal after obtaining output digital values corresponding to signal levels of samples obtained during the first sampling phase, for averaging.

3. The ADC of claim 1, further comprising:
a first capacitor and a second capacitor charged separately based on a corresponding input analog signal of the first input analog signal and the second input analog signal during a sampling phase.

4. The ADC of claim 3, further comprising:
a first chopper configured to couple a corresponding input analog signal of the first input analog signal and the second input analog signal separately to the first capacitor and the second capacitor.

5. The ADC of claim 4, further comprising:
a second chopper configured to convert an output of the comparator.

6. The ADC of claim 1, wherein the controller is configured to incrementally generate the first digital value and the second digital value during the first conversion phase.

7. The ADC of claim 1, wherein the controller is configured to input the first digital for determining a least significant bit (LSB) of an output digital value of the ADC into the second DAC before a second sampling phase, and input the second digital value for determining the LSB into the first DAC before the second sampling phase.

8. The ADC of claim 7, wherein the controller is configured to input the first digital value into the second DAC and input the second digital value into the first DAC between a falling edge of a clock signal for the first conversion phase and a last rising edge of a clock signal for driving the comparator within the first conversion phase.

9. The ADC of claim 1, wherein the controller is configured to generate an output digital value corresponding to a difference between respective sample values obtained from the first input analog signal and the second input analog signal during a sampling phase corresponding to a conversion phase, based on values output from the comparator during the conversion phase.

10. The ADC of claim 9, wherein the controller is configured to perform averaging on respective output digital values of the ADC generated during a plurality of conversion phases.

11. An analog-to-digital converter (ADC) comprising:
a first digital-to-analog converter (DAC) configured to change a signal level of a first node based on one of a first input analog signal and a second input analog signal;
a second DAC configured to change a signal level of a second node based on one of the first input analog signal and the second input analog signal;
a comparator configured to compare the signal level of the first node and the signal level of the second node;
a controller configured to generate an output digital value corresponding to a difference between respective sample values obtained from the first input analog signal and the second input analog signal during a sampling phase corresponding to a conversion phase, based on values output from the comparator during the conversion phase; and
a code swap circuit configured to input an input digital value of the first DAC generated during a first conversion phase corresponding to a first sampling phase into the second DAC before a second sampling phase, and input an input digital value of the second DAC generated during the first conversion phase into the first DAC before the second sampling phase.

12. A method comprising:
changing a signal level of a first node and a signal level of a second node separately based on a corresponding input analog signal of a first input analog signal and a second input analog signal;
comparing, using a comparator, the signal level of the first node and the signal level of the second node;
inputting, using a controller, an input digital value of a first digital-to-analog converter (DAC) generated during a first conversion phase corresponding to a first sampling phase into a second DAC before a second sampling phase; and
inputting an input digital value of the second DAC generated during the first conversion phase into the first DAC before the second sampling phase,
wherein the first DAC is coupled to the first node, and
the second DAC is coupled to the second node.

13. The method of claim 12, wherein the second sampling phase is for sampling the first input analog signal and the second input analog signal after obtaining output digital values corresponding to signal levels of samples obtained during the first sampling phase, for averaging.

14. The method of claim 12, further comprising:
coupling, using a first chopper, each corresponding input analog signal of the first input analog signal and the second input analog signal to a first capacitor and a second capacitor,
wherein the first capacitor and the second capacitor are charged separately based on each corresponding input analog signal of the first input analog signal and the second input analog signal during a sampling phase.

15. The method of claim 14, further comprising:
converting, using a second chopper, an output of the comparator.

16. The method of claim 12, wherein the inputting of the input digital value of the first DAC generated during the first conversion phase into the second DAC before the second sampling phase comprises inputting the input digital value of the first DAC for determining a least significant bit (LSB) of an output digital value into the second DAC before the second sampling phase.

17. The method of claim 16, wherein the inputting of the input digital value of the second DAC generated during the first conversion phase into the first DAC before the second sampling phase comprises inputting the input digital value of the second DAC for determining the LSB into the first DAC before the second sampling phase.

18. The method of claim 16, wherein the inputting of the input digital value of the first DAC for determining the LSB into the second DAC before the second sampling phase comprises inputting the input digital value of the first DAC for determining the LSB into the second DAC, between a falling edge of a clock signal for the first conversion phase and a last rising edge of a clock signal for driving the comparator within the first conversion phase.

19. The method of claim 17, wherein the inputting of the input digital value of the second DAC for determining the LSB into the first DAC before the second sampling phase comprises inputting the input digital value of the second DAC for determining the LSB into the first DAC, between a falling edge of a clock signal for the first conversion phase and a last rising edge of a clock signal for driving the comparator within the first conversion phase.

20. The method of claim 12, further comprising:
generating, using the controller, an output digital value corresponding to a difference between respective sample values obtained from the first input analog signal and the second input analog signal during a sampling phase corresponding to a conversion phase, based on values output from the comparator during the conversion phase.

21. (canceled)
